(19) United States
(12) Patent Application Publication
(10) Pub. No.: US 2005/0214457 A1
(43) Pub. Date: Sep. 29, 2005

(54) Deposition of low dielectric constant films by N2O addition

(75) Inventors: Francimar Schmitt, Santa Clara, CA (US); Kimberly A. Branshaw, Santa Clara, CA (US); Padmanabhan Krishnaraj, San Francisco, CA (US); Hichem M'Saad, Santa Clara, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(73) Assignee: Applied Materials, Inc.

(21) Appl. No.: 10/812,717

(22) Filed: Mar. 29, 2004

(51) Int. Cl. C23C 16/00

(52) U.S. Cl. 427/248.1

(57) ABSTRACT

A method for depositing a low dielectric constant film includes providing a gas mixture including a cyclic organosiloxane and N₂O as an oxidizing gas to a chamber and applying RF power to the gas mixture to deposit a low dielectric constant film. The gas mixture may also include oxygen and/or a linear hydrocarbon. In one aspect, the gas mixture includes N₂O and oxygen as oxidizing gases, and a ratio of the flow rate of the N₂O to a total flow rate of the N₂O and the oxygen is between about 0.1 and about 0.5.

### BACKGROUND OF THE INVENTION

1. Field of the Invention

Embodiments of the present invention relate to the fabrication of integrated circuits. More particularly, embodiments of the present invention relate to a process for depositing dielectric layers on a substrate.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 0.13 μm and even 0.1 μm feature sizes, and tomorrow's facilities soon will be producing devices having even smaller feature sizes.

The continued reduction in device geometries has generated a demand for films having lower dielectric constant (k) values because the capacitive coupling between adjacent metal lines must be reduced to further reduce the size of devices on integrated circuits. In particular, insulators having low dielectric constants, less than about 4.0, are desirable. Examples of insulators having low dielectric constants include spin-on glass, such as un-doped silicon glass (USG) or fluorine-doped silicon glass (FSG), silicon dioxide, and polytetrafluoroethylene (PTFE), which are all commercially available.

More recently, organosilicon films that include silicon, carbon, and oxygen and have k values less than about 3.5 have been developed. While organosilicon films having desirable dielectric constants have been developed, many known low dielectric organosilicon films have undesirable physical or mechanical properties, such as high tensile stress. High tensile stress in a film can lead to film bowing or deformation, film cracking, film peeling, or the formation of voids in the film, which can damage or destroy a device that includes the film.

There is a need, therefore, for a controllable process for making lower dielectric constant films that have desirable physical or mechanical properties.

### SUMMARY OF THE INVENTION

Embodiments of the invention provide a method of depositing a low dielectric constant film from a gas mixture including a cyclic organosiloxane and nitrous oxide (N₂O) as an oxidizing gas. In one embodiment, a method for depositing a low dielectric constant film comprises delivering a gas mixture including a cyclic organosiloxane and two or more oxidizing gases comprising N₂O and oxygen gas (O₂) to a substrate in a chamber, wherein a ratio of a flow rate of the N₂O to a total flow rate of the two or more oxidizing gases into the chamber is from about 0.1 to about 0.5, and applying RF power to the gas mixture at conditions sufficient to deposit a low dielectric constant film on a surface of the substrate. In one aspect, the two or more oxidizing gases consist of N₂O and O₂.

Embodiments of the invention also include delivering a gas mixture comprising a cyclic organosiloxane and an oxidizing gas comprising N₂O to a substrate in a chamber, wherein the N₂O is delivered into the chamber at a flow rate between about 0.71 sccm/cm² and about 1.42 sccm/cm², and applying RF power to the gas mixture at conditions sufficient to deposit a low dielectric constant film on a surface of the substrate.

Further embodiments of the invention include delivering a gas mixture comprising a cyclic organosiloxane, a linear hydrocarbon having at least one unsaturated carbon-carbon bond, and two or more oxidizing gases comprising N₂O and O₂ to a substrate in a chamber, and applying RF power to the gas mixture at conditions sufficient to deposit a low dielectric constant film on a surface of the substrate. In one embodiment, the linear hydrocarbon is ethylene.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional diagram of an exemplary CVD reactor configured for use according to embodiments described herein.

FIG. 2 is an electron beam chamber in accordance with an embodiment of the invention.

FIG. 3 is a fragmentary view of the electron beam chamber in accordance with an embodiment of the invention.

### DETAILED DESCRIPTION OF THE PREFERRED EMBODIMENT

Embodiments of the invention provide low dielectric constant films containing silicon, oxygen, and carbon by providing a gas mixture comprising a cyclic organosiloxane and N₂O to a chamber and applying RF power to the gas mixture to deposit a low dielectric constant film. Preferably, the low dielectric constant film has a dielectric constant of less than about 2.95.

The cyclic organosiloxane includes compounds having one or more silicon-carbon bonds. Commercially available cyclic organosiloxane compounds that include one or more rings having alternating silicon and oxygen atoms with one or two alkyl groups bonded to the silicon atoms may be used. In one embodiment, the low dielectric constant film may be deposited from a gas mixture comprising one or more cyclic organosiloxanes. For example, the one or more cyclic organosiloxanes may be one or more of the following compounds:
1,3,5-trimethylcyclotrisiloxane —(SiHCH₃—O—)₃— (cyclic)
hexamethylcyclotrisiloxane, —(—Si(CH₃)₂—O—)₃— (cyclic)
1,3,5,7-tetramethylcyclotetrasiloxane (TMCTS), —(—SiHCH₃—O—)₄— (cyclic)
octamethylcyclotetrasiloxane (OMCTS), —(—Si(CH₃)₂—O—)₄— (cyclic)
1,3,5,7,9-pentamethylcyclopentasiloxane, —(—SiHCH₃—O—)₅— (cyclic)
decamethylcyclopentasiloxane —(—Si(CH₃)₂—O—)₅— (cyclic).

One or more inert carrier gases may be mixed/blended with the cyclic organosiloxane. The one or more inert gases may include argon, helium, or combinations thereof.

In all of the embodiments described herein, the gas mixture includes N₂O as an oxidizing gas. In one embodiment, the gas mixture comprises a cyclic organosiloxane and two or more oxidizing gases comprising N₂O and O₂. Preferably, the only oxidizing gases in the gas mixture are N₂O and O₂. The ratio of the flow rate of the N₂O to a total flow rate of the two or more oxidizing gases into the chamber is from about 0.1 to about 0.5.

In another embodiment, the gas mixture comprises a cyclic organosiloxane and an oxidizing gas comprising N₂O. The N₂O is delivered into the chamber at a flow rate between about 0.71 sccm/cm² and about 1.42 sccm/cm², which corresponds to a N₂O flow rate of about 500 to about 1000 sccm for a 300 mm substrate. Preferably, the only oxidizing gas in the gas mixture is N₂O. Optionally, the gas mixture may further comprise a linear hydrocarbon. The linear hydrocarbon compound has at least one unsaturated carbon-carbon bond. The unsaturated carbon-carbon bond may be a double bond or a triple bond. The linear hydrocarbon compound may include one or two carbon-carbon double bonds. As defined herein, a “linear hydrocarbon compound” includes hydrogen and carbon atoms, but does not include oxygen, nitrogen, or fluorine atoms. Preferably, the linear hydrocarbon compound includes only carbon and hydrogen atoms. The linear hydrocarbon compound may be an alkene, alkylene, or diene having two to about 20 carbon atoms, such as ethylene, propylene, isobutylene, acetylene, allylene, ethylacetylene, 1,3-butadiene, isoprene, 2,3-dimethyl-1,3-butadiene, and piperylene.

In another embodiment, the gas mixture comprises a cyclic organosiloxane, a linear hydrocarbon having at least on unsaturated carbon-carbon bond, and two or more oxidizing gases comprising N₂O and O₂. In a preferred embodiment, the only oxidizing gases in the gas mixture are N₂O and O₂.

In all of the embodiments described herein, RF power is applied to the gas mixture comprising a cyclic organosiloxane and N₂O to form a low dielectric constant film on the substrate. The RF power provided to a 200 or 300 mm substrate is between about 0.03 W/cm² and about 3.2 W/cm², which corresponds to a RF power level of about 10 W to about 1,000 W for a 200 mm substrate and about 20 W to about 2,250 W for a 300 mm substrate. Preferably, the RF power level is between about 200 W and about 1,700 W for a 300 mm substrate.

The films contain a carbon content between about 5 and about 30 atomic percent (excluding hydrogen atoms), preferably between about 5 and about 20 atomic percent. The carbon content of the deposited films refers to atomic analysis of the film structure which typically does not contain significant amounts of non-bonded hydrocarbons. The carbon contents are represented by the percent of carbon atoms in the deposited film, excluding hydrogen atoms which are difficult to quantify. For example, a film having an average of one silicon atom, one oxygen atom, one carbon atom, and two hydrogen atoms has a-carbon content of 20 atomic percent (one carbon atom per five total atoms), or a carbon content of 33 atomic percent excluding hydrogen atoms (one carbon atom per three total atoms).

In any of the embodiments described herein, after the low dielectric constant film is deposited, the film may be treated with an electron beam (e-beam) to reduce the dielectric constant of the film. The electron beam treatment typically has a dose between about 50 and about 2000 micro coulombs per square centimeter (μc/cm²) at about 1 to 20 kiloelectron volts (KeV). The e-beam current typically ranges from about 1 mA to about 40 mA, and is preferably-about 10 to about 20 mA. The e-beam treatment is typically operated at a temperature between about room-temperature and about 450° C. for about 10 seconds to about 15 minutes. In one aspect, the e-beam treatment conditions include 6 kV, 10-18 mA and 50 μc/cm² at 350° C. for about 15 to about 30 seconds to treat a film having a thickness of about 1 micron. In another aspect, the e-beam treatment conditions include 4.5 kV, 10-18 mA and 50 μc/cm² at 350° C. for about 15 to about 30 seconds to treat a film having a thickness of about 5000 Å. Argon or hydrogen may be present during the electron beam treatment. Although any e-beam device may be used, one exemplary device is the EBK chamber, available from Applied Materials, Inc. Treating the low dielectric constant film with an electron beam after the low dielectric constant film is deposited will volatilize at least some of the organic groups in the film which may form voids in the film.

Alternatively, in another embodiment, after the low dielectric constant film is deposited, the film is post-treated with an annealing process to reduce the dielectric constant of the film. Preferably, the film is annealed at a temperature between about 200° C. and about 400° C. for about 2 seconds to about 1 hour, preferably about 30 minutes. A non-reactive gas such as helium, hydrogen, nitrogen, or a mixture thereof is introduced at a rate of 100 to about 10,000 sccm. The chamber pressure is maintained between about 2 Torr and about 10 Torr. The RF power is about 200 W to about 1,000 W at a frequency of about 13.56 MHz, and the preferable substrate spacing is between about 300 mils and about 800 mils.

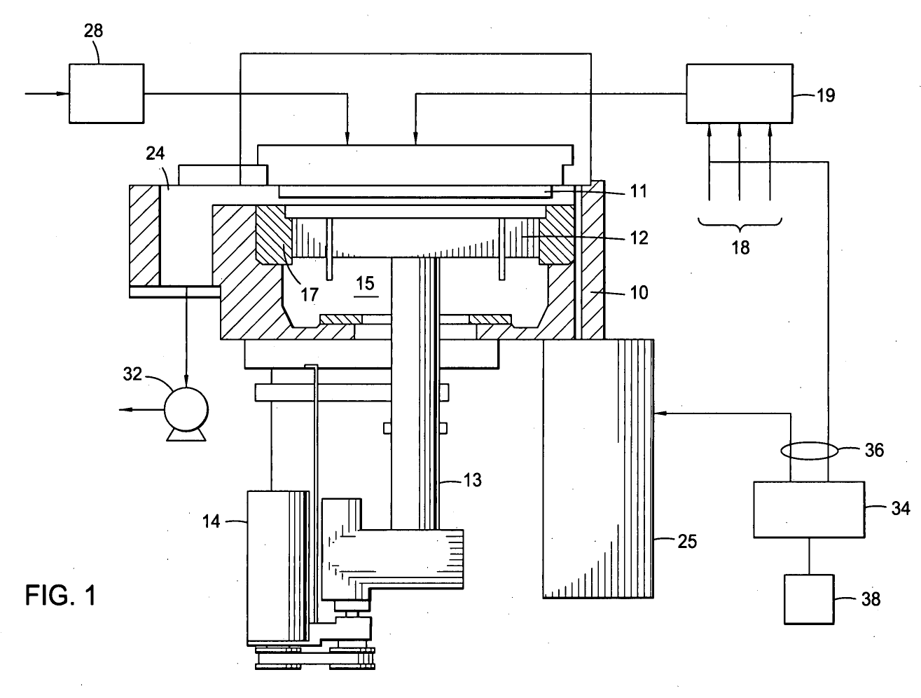

The film may be deposited using any processing chamber capable of chemical vapor deposition (CVD). For example, FIG. 1 shows a vertical, cross-section view of a parallel plate CVD processing chamber 10. The chamber 10 includes a high vacuum region 15 and a gas distribution manifold 11 having perforated holes for dispersing process gases there-through to a substrate (not shown). The substrate rests on a substrate support plate or susceptor 12. The susceptor 12 is mounted on a support stem 13 that connects the susceptor 12 to a lift motor 14. The lift motor 14 raises and lowers the susceptor 12 between a processing position and a lower, substrate-loading position so that the susceptor 12 (and the substrate supported on the upper surface of susceptor 12) can be controllably moved between a lower loading/off-loading position and an upper processing position which is closely adjacent to the manifold 11. An insulator 17 surrounds the susceptor 12 and the substrate when in an upper processing position.

Gases introduced to the manifold 11 are uniformly distributed radially across the surface of the substrate. A vacuum pump 32 having a throttle valve controls the exhaust rate of gases from the chamber 10 through a manifold 24. Deposition and carrier gases, if needed, flow through gas lines 18 into a mixing system 19 and then to the manifold 11. Generally, each process gas supply line 18 includes (i) safety shut-off valves (not shown) that can be used to automatically or manually shut off the flow of process gas into the chamber, and (ii) mass flow controllers (also not shown) to measure the flow of gas through the gas supply lines 18. When toxic gases are used in the process, several safety shut-off valves are positioned on each gas supply line 18 in conventional configurations.

In one aspect, the cyclic organosilbxane is introduced to the mixing system 19 at a flow rate of about 75 sccm to about 500 sccm. The flow rates of the one or more oxidizing gases comprising N₂O are provided in the description of embodiments provided above. The one or more inert gases have a total flow rate of about 100 sccm to about 5,000 sccm. The optional linear hydrocarbon is introduced at a flow rate of up to about 3,000 sccm. Preferably, the cyclic organosilicon compound is octamethylcyclotetrasiloxane, the inert gas is helium, and the linear hydrocarbon is ethylene.

The flow rates described above are provided with respect to a 300 mm chamber having two isolated processing regions and may vary depending on the size of the processing chamber used.

The deposition process is preferably a plasma enhanced process. In a plasma enhanced process, a controlled plasma is typically formed adjacent the substrate by RF energy applied to the gas distribution manifold 11 using a RF power supply 25. Alternatively, RF power can be provided to the susceptor 12. The RF power to the deposition chamber may be cycled or pulsed to reduce heating of the substrate and promote greater porosity in the deposited film.

The RF power supply 25 can supply a single frequency RF power between about 0.01 MHz and 300 MHz. Preferably, the RF power may be delivered using mixed, simultaneous frequencies to enhance the decomposition of reactive species introduced into the high vacuum region 15. In one aspect, the mixed frequency is a lower frequency of about 12 kHz and a higher frequency of about 13.56 mHz. In another aspect, the lower frequency may range between about 300 Hz to about 1,000 kHz, and the higher frequency may range between about 5 mHz and about 50 mHz. Preferably, the low frequency power level is about 150 W. Preferably, the high frequency power level is about 200 W to about 750 W, more preferably, about 200 W to about 400 W.

During deposition, the substrate is maintained at a temperature between about −20° C. and about 500° C., preferably between about 100° C. and about 450° C. The deposition pressure is typically between about 2 Torr and about 10 Torr, preferably between about 4 Torr and about 7 Torr. The deposition rate is typically between about 3,000 Å/min and about 15,000 Å/min.

When additional dissociation of the oxidizing gas is desired, an optional microwave chamber 28 can be used to input power from between about 50 Watts and about 6,000 Watts to the oxidizing gas prior to the gas entering the processing chamber 10. The additional microwave power can avoid excessive dissociation of the organosilicon compounds prior to reaction with the oxidizing gas. A gas distribution plate (not shown) having separate passages for the organosilicon compound and the oxidizing gas is preferred when microwave power is added to the oxidizing gas.

Typically, any or all of the chamber lining, distribution manifold 11, susceptor 12, and various other reactor hardware is made out of materials such as aluminum or anodized aluminum. An example of such a CVD reactor is described in U.S. Pat. No. 5,000,113, entitled “A Thermal CVD/PECVD Reactor and Use for Thermal Chemical Vapor Deposition of Silicon Dioxide and In-situ Multi-step Planarized Process,” which is incorporated by reference herein.

A system controller 34 controls the motor 14, the gas mixing system 19, and the RF power supply 25 which are connected therewith by control lines 36. The system controller 34 controls the activities of the CVD reactor and typically includes a hard disk drive, a floppy disk drive, and a card rack. The card rack contains a single board computer (SBC), analog and digital input/output boards, interface boards, and stepper motor controller boards. The system controller 34 conforms to the Versa Modular Europeans (VME) standard which defines board, card cage, and connector dimensions and types. The VME standard also defines the bus structure having a 16-bit data bus and 24-bit address bus. The system controller 34 operates under the control of a computer program stored on a hard disk drive 38.

The above CVD system description is mainly for illustrative purposes, and other CVD equipment such as electrode cyclotron resonance (ECR) plasma CVD devices, induction-coupled RF high density plasma CVD devices, or the like may be employed. Additionally, variations of the above described system such as variations in susceptor design, heater design, location of RF power connections and others are possible. For example, the substrate could be supported and heated by a resistively heated susceptor.

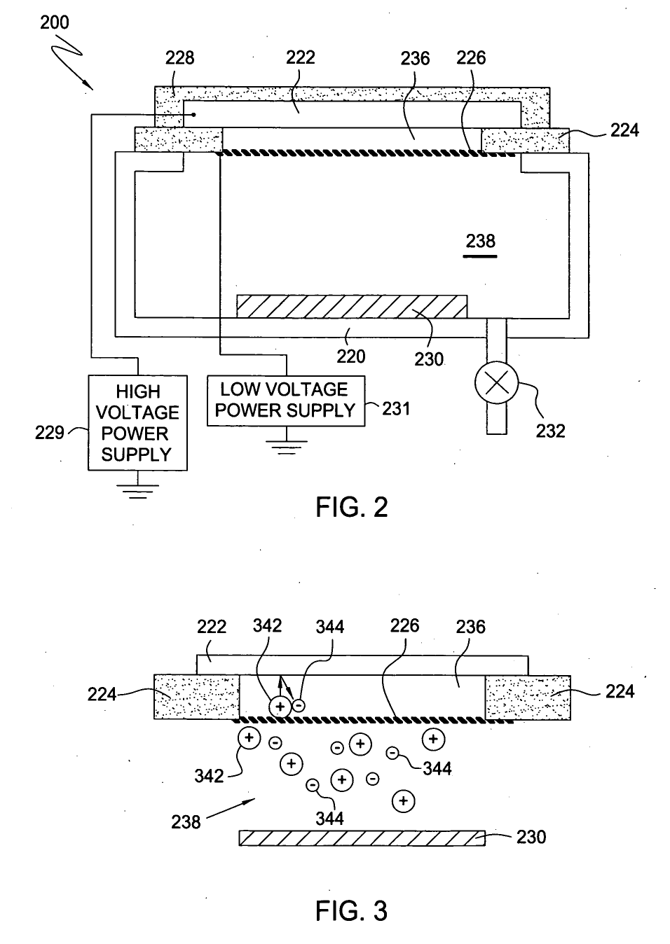

Once the film is deposited, the substrate may be transferred to an electron beam (e-beam) apparatus for further processing, i.e., curing. The substrate may be transferred with a vacuum break or under vacuum, i.e., without any vacuum break. FIG. 2 illustrates an e-beam chamber 200 in accordance with an embodiment of the invention. The e-beam chamber 200 includes a vacuum chamber 220, a large-area cathode 222, a target plane 230 located in a field-free region 238, and a grid anode 226 positioned between the target plane 230 and the large-area cathode 222. The e-beam chamber 200 further includes a high voltage insulator 224, which isolates the grid anode 226 from the large-area cathode 222, a cathode cover insulator 228 located outside the vacuum chamber 220, a variable leak valve 232 for controlling the pressure inside the vacuum chamber 220, a variable high voltage power supply 229 connected to the large-area cathode 222, and a variable low voltage power supply 231 connected to the grid anode 226.

In operation, the substrate (not shown) to be exposed with the electron beam is placed on the target plane 230. The vacuum chamber 220 is pumped from atmospheric pressure to a pressure in the range of about 1 mTorr to about 200 mTorr. The exact pressure is controlled by the variable rate leak valve 232, which is capable of controlling pressure to about 0.1 mTorr. The electron beam is generally generated at a sufficiently high voltage, which is applied to the large-area cathode 222 by the high voltage power supply 229. The voltage may range from about −500 volts to about 30,000 volts or higher. The high voltage power supply 229 may be a Bertan Model #105-30R manufactured by Bertan of Hickville, N.Y., or a Spellman Model #SL30N-1200X 258 manufactured by Spellman High Voltage Electronics Corp., of Hauppauge, N.Y. The variable low voltage power supply 231 applies a voltage to the grid anode 226 that is positive relative to the voltage applied to the large-area cathode 222. This voltage is used to control electron emission from the large-area cathode 222. The variable low voltage power supply 231 may be an Acopian Model #150PT12 power supply available from Acopian of Easton, Pa.

To initiate electron emission, the gas in the field-free region 238 between the grid anode 226 and the target plane 30 must become ionized, which may occur as a result of naturally occurring gamma rays. Electron emission may also be artificially initiated inside the vacuum chamber 220 by a high voltage spark gap. Once this initial ionization takes place, positive ions 342 (shown in FIG. 3) are attracted to the grid anode 226 by a slightly negative voltage, i.e., on the order of about 0 to about −200 volts, applied to the grid anode 226. These positive ions 342 pass into the accelerating field region 236, disposed between the large-area cathode 222 and the grid anode 226, and are accelerated towards the large-area cathode 222 as a result of the high voltage applied to the large-area cathode 222. Upon striking the large-area cathode 222, these high-energy ions produce secondary electrons 344, which are accelerated back toward the grid anode 226. Some of these electrons 344, which travel generally perpendicular to the cathode surface, strike the grid anode 226, but many of these electrons 344 pass through the grid anode 226 and travel to the target plane 230. The grid anode 226 is preferably positioned at a distance less than the mean free path of the electrons emitted by the large-area cathode 222, e.g., the grid anode 226 is preferably positioned less than about 4 mm from the large-area cathode 222. Due to the short distance between the grid anode 226 and the large-area cathode 222, no, or minimal if any, ionization takes place in the accelerating field region 236 between the grid anode 226 and the large-area cathode 222.

In a conventional gas discharge device, the electrons would create further positive ions in the accelerating field region, which would be attracted to the large-area cathode 222, creating even more electron emission. The discharge could easily avalanche into an unstable high voltage breakdown. However, in accordance with an embodiment of the invention, the ions 342 created outside the grid anode 226 may be controlled (repelled or attracted) by the voltage applied to the grid anode 226. In other words, the electron emission may be continuously controlled by varying the voltage on the grid anode 226. Alternatively, the electron emission may be controlled by the variable leak valve 232, which is configured to raise or lower the number of molecules in the ionization region between the target plane 230 and the large-area cathode 222. The electron emission may be entirely turned off by applying a positive voltage to the grid anode 226, i.e., when the grid anode-voltage exceeds the energy of any of the positive ion species created in the space between the grid anode 226 and target plane 230.

Other details of the e-beam chamber 200 are described in U.S. Pat. No. 5,003,178, entitled “Large-Area Uniform Electron Source”, issued to William R. Livesay, assigned to Electron Vision Corporation (which is currently owned by the assignee of the present invention) and is incorporated by reference herein to the extent not inconsistent with the invention.

### EXAMPLES

The following examples illustrate low dielectric constant films of the present invention. The films were deposited using a chemical vapor deposition chamber that is part of an integrated processing platform. In particular, the films were deposited using a Producers SE 300 mm system having a CVD chamber having two isolated processing regions, available from Applied Materials, Inc. of Santa Clara, Calif.

### Example 1

A low dielectric constant film was deposited on a 300 mm substrate from the following reactive gases at a chamber pressure of about 5 Torr and substrate temperature of about 350° C.
Octamethylcyclotetrasiloxane (OMCTS), at about 227 sccm;
Nitrous oxide (N₂O), at about 30 sccm;
Oxygen (O₂), at about 145 sccm; and
Helium (He), at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,205 Å/min, and had a dielectric constant (k) of about 2.82 measured at 0.1 MHz. The film had a tensile stress of 33.33 MPa. The ratio of the flow rate of the N₂O to the total flow rate of the N₂O and the O₂ was 0.17.

### Example 2

A low dielectric constant film was deposited on a 300 mm substrate from the following reactive gases at a chamber pressure of about 5 Torr and substrate temperature of about 350° C.
OMCTS, at about 227 sccm;
N₂O, at about 60 sccm;
O₂, at about 130 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,317 Å/min, and had a dielectric constant (k) of about 2.80 measured at 0.1 MHz. The film had a tensile stress of 30.60 MPa. The ratio of the flow rate of the N₂O to the total flow rate of the N₂O and the O₂ was 0.32.

### Example 3

A low dielectric constant film was deposited on a 300 mm substrate from the following reactive gases at a chamber pressure of about 5 Torr and substrate temperature of about 350° C.
OMCTS, at about 227 sccm;
N₂O, at about 100 sccm;
O₂, at about 110 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,265 Å/min, and had a dielectric constant (k) of about 2.81 measured at 0.1 MHz. The film had a tensile stress of 21.17 MPa. The ratio of the flow rate of the N₂O to the total flow rate of the N₂O and the O₂ was 0.48.

### Comparison Example 1

A low dielectric constant film was deposited on a 300 mm substrate from the following reactive gases at a chamber pressure of about 5 Torr and substrate temperature of about 350° C.
OMCTS, at about 227 sccm;
O₂, at about 160 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 5,980 Å/min, and had a dielectric constant (k) of about 2.86 measured at 0.1 MHz. The film had a tensile stress of 20.10 MPa. As no N₂O was used, the ratio of the flow rate of N₂O to the total flow rate of N₂O and the O₂ was 0.

### Comparison Example 2

A low dielectric constant film was deposited on a 300 mm substrate from the following reactive gases at a chamber pressure of about 5 Torr and substrate temperature of about 350° C.
OMCTS, at about 227 sccm;
N₂O, at about 160 sccm;
O₂, at about 80 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,270 Å/min, and had a dielectric constant (k) of about 2.83 measured at 0.1 MHz. The film had a tensile stress of 17.0 MPa. The ratio of the flow rate of the N₂O to the total flow rate of the N₂O and the O₂ was 0.67.

### Comparison Example 3

A low dielectric constant film was deposited on a 300 mm substrate from the following reactive gases at a chamber pressure of about 5 Torr and substrate temperature of about 350° C.
Octamethylcyclotetrasiloxane (OMCTS), at about 227 sccm;
N₂O, at about 240 sccm;
O₂, at about 40 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film, was deposited at a rate of about 6,328 Å/min, and had a dielectric constant (k) of about 2.83 measured at 0.1 MHz. The film had a tensile stress of 15.0 MPa. The ratio of the flow rate of the N₂O to the total flow rate of the N₂O and the O₂ was 0.86.

### Example 4

A low dielectric constant film was deposited on a 300 mm substrate from the following reactive gases at a chamber pressure of about 5 Torr and substrate temperature of about 350° C.
OMCTS, at about 227 sccm;
N₂O, at about 500 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 7,512 Å/min, and had a dielectric constant (k) of about 2.82 measured at 0.1 MHz. The film had a tensile stress of 15.1 MPa. After e-beam treatment, the film had a dielectric constant of about 2.78 and a tensile stress of 29.66 MPa.

### Example 5

A low dielectric constant film was deposited on a 300 mm substrate from the following reactive gases at a chamber pressure of about 5 Torr and substrate temperature of about 350° C.
OMCTS, at about 227 sccm;
N₂O, at about 700 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 9,009 Å/min, and had a dielectric constant (k) of about 2.82 measured at 0.1 MHz. The film had a tensile stress of 22.51 MPa.

### Comparison Example 4

A low dielectric constant film was deposited on a 300 mm substrate from the following reactive gases at a chamber pressure of about 5 Torr and substrate temperature of about 350° C.
OMCTS, at about 227 sccm;
N₂O, at about 100 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 5,219 Å/min, and had a dielectric constant (k) of about 2.93 measured at 0.1 MHz. The film had a tensile stress of 5.67 MPa. After e-beam treatment, the film had a dielectric constant of about 2.90 and a tensile stress of 24.78 MPa.

### Comparison Example 5

A low dielectric constant film was deposited on a 300 mm substrate from the following reactive gases at a chamber pressure of about 5 Torr and substrate temperature of about 350° C.
OMCTS, at about 227 sccm;
N₂O, at about 250 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,027 Å/min, and had a dielectric constant (k) of about 2.87 measured at 0.1 MHz. The film had a tensile stress of 8.35 MPa. After e-beam treatment, the film had a dielectric constant of about 2.84 and a tensile stress of 26.3 MPa.

### Example 6

A low dielectric constant film was deposited on a 300 mm substrate from the following reactive gases at a chamber pressure of about 5 Torr and substrate temperature of about 350° C.
OMCTS, at about 227 sccm;
Ethylene (C₂H₄), at about 250 sccm;
N₂O, at about 600 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 7,329 Å/min, and had a dielectric constant (k) of about 2.80 measured at 0.1 MHz. The film had a tensile stress of 16.0 MPa.

### Example 7

A low dielectric constant film was deposited on a 300 mm substrate from the following reactive gases at a chamber pressure of about 5 Torr and substrate temperature of about 350° C.
OMCTS, at about 227 sccm;
C₂H₄, at about 1,000 sccm;
N₂O, at about 600 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 5,540 Å/min, and had a dielectric constant (k) of about 2.80 measured at 0.1 MHz. The film had a tensile stress of 11.76 MPa.

### Example 8

A low dielectric constant film was deposited on a 300 mm substrate from the following reactive gases at a chamber pressure of about 5 Torr and substrate temperature of about 350° C.
OMCTS, at about 227 sccm;
C₂H₄, at about 2,000 sccm;
N₂O, at about 600 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 4,301 Å/min, and had a dielectric constant (k) of about 2.84 measured at 0.1 MHz. The film had a tensile stress of 2.95 MPa.

### Example 9

A low dielectric constant film was deposited on a 300 mm substrate from the following reactive gases at a chamber pressure of about 5 Torr and substrate temperature of about 350° C.
OMCTS, at about 227 sccm;
C₂H₄, at about 3,000 sccm;
N₂O, at about 600 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 3,578 Å/min, and had a dielectric constant (k) of about 2.91 measured at 0.1 MHz. The film had a compressive stress of −7.61 MPa.

### Example 10

A low dielectric constant film was deposited on a 300 mm substrate from the following reactive gases at a chamber pressure of about 5 Torr and substrate temperature of about 350° C.
OMCTS, at about 227 sccm;
C₂H₄, at about 250 sccm;
N₂O, at about 160 sccm;
O₂, at about 80 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 6,014 Å/min, and had a dielectric constant (k) of about 2.79 measured at 0.1 MHz. The film had a tensile stress of 15 MPa. After e-beam treatment, the film had a dielectric constant of about 2.75 and a tensile stress of 29.6 MPa.

### Example 11

A low dielectric constant film was deposited on a 300 mm substrate from the following reactive gases at a chamber pressure of about 5 Torr and substrate temperature of about 350° C.
OMCTS, at about 227 sccm;
C₂H₄, at about 1,000 sccm;
N₂O, at about 160 sccm;
O₂, at about 80 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 4,788 Å/min, and had a dielectric constant (k) of about 2.82 measured at 0.1 MHz. The film had a tensile stress of 7.15 MPa. After e-beam treatment, the film had a dielectric constant of about 2.78 and a tensile stress of 25 MPa.

### Example 12

A low dielectric constant film was deposited on a 300 mm substrate from the following reactive gases at a chamber pressure of about 5 Torr and substrate temperature of about 350° C.
OMCTS, at about 227 sccm;
C₂H₄, at about 2,000 sccm;
N₂O, at about 160 sccm;
O₂, at about 80 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 3,939 Å/min, and had a dielectric constant (k) of about 2.87 measured at 0.1 MHz. The film had a compressive stress of −6.16 MPa. After e-beam treatment, the film had a dielectric constant of about 2.82 and a tensile stress of 16.25 MPa.

### Example 13

A low dielectric constant film was deposited on a 300 mm substrate from the following reactive gases at a chamber pressure of about 5 Torr and substrate temperature of about 350° C.
OMCTS, at about 227 sccm;
C₂H₄, at about 3,000 sccm;
N₂O, at about 160 sccm;
O₂, at about 80 sccm; and
He, at about 1,000 sccm

The substrate was positioned 450 mils from the gas distribution showerhead. A power level of about 500 W at a frequency of 13.56 MHz and a power level of about 150 W at a frequency of 350 kHz were applied to the showerhead for plasma enhanced deposition of the film. The film was deposited at a rate of about 3,522 Å/min, and had a dielectric constant (k) of about 2.92 measured at 0.1 MHz. The film had a compressive stress of −22.1 MPa. After e-beam treatment, the film had a dielectric constant of about 2.88 and a tensile stress of 2.52 MPa.

Examples 1-3 and Comparison Examples 1-3 show the processing conditions that were used to deposit low dielectric constant films from gas mixtures that included OMCTS, N₂O, O₂, and He. The films of Examples 1-3 had dielectric constants of less than 2.83 and tensile stresses of less than 34 MPa. The films of Comparison Examples 1-3 also had tensile stresses of less than 34 MPa. However, the films of Comparison Examples 1-3 had dielectric constants of greater than 2.83. As defined herein, a film that has tensile stress is a film that has a stress of greater than 0 MPa, as measured by a FSM 128L tool, available from Frontier Semiconductor, San Jose, Calif. As defined herein, a film that has compressive stress is a film that has a stress of less than 0 MPa, as measured by a FSM 128L tool. Thus, it was found that for gas mixtures comprising OMCTS, N₂O, O₂, and He, films deposited from the gas mixtures having a ratio of N₂O flow rate to a total flow rate of the N₂O flow rate and the O₂ flow rate of about 0.1 to about 0.5 had lower dielectric constants than films deposited from mixtures having other ratios of N₂O flow rate to a total flow rate of the N₂O flow rate and the O₂ flow rate.

Examples 4-5 and Comparison Examples 4-5 show the processing conditions that were used to deposit low dielectric constant films from gas mixtures that included OMCTS, N₂O, and He. The films of Examples 4-5 had dielectric constants of less than 2.83 and tensile stresses of less than 30 MPa. The films of Comparison Examples 4-5 also had tensile stresses of less than 30 MPa. However, the films of Comparison Examples 4-5 had dielectric constants of greater than 2.83. Thus, it was found that for gas mixtures comprising OMCTS, N₂O, and He, films deposited from the gas mixtures in which N₂O is introduced into the chamber at a flow rate of about 500 to about 1000 sccm for a 300 mm substrate, i.e., at a N₂O flow rate between about 0.71 sccm/cm² and about 1.42 sccm/cm², had lower dielectric constants than films deposited from gas mixtures in which N₂O is introduced into the chamber at other flow rates.

Examples 6-9 show the processing conditions that were used to deposit low dielectric constant films from gas mixtures that included OMCTS, N₂O, C₂H₄, and He. The films of Examples 6-9 had dielectric constants of less than 2.92 and stresses of less than 17 MPa. The films of Examples 6-8 had tensile stresses, and the film of Example 9, which was deposited from a gas mixture having a larger amount of C₂H₄ than the mixtures of Examples 6-8, had compressive stress.

Examples 10-13 show the processing conditions that were used to deposit low dielectric constant films from gas mixtures that included OMCTS, N₂O, O₂, C₂H₄, and He. The films of Examples 10-13 had dielectric constants of less than 2.93 and stresses of less than 30 MPa. The films of Examples 10-11 had tensile stresses, and the films of Example 12-13, which were deposited from gas mixtures having a larger amount of C₂H₄ than the mixtures of Examples 10-11, had compressive stresses.

Thus, embodiments of the invention provide methods of depositing low dielectric constant films from gas mixtures comprising a cyclic siloxane and N₂O as an oxidizer. The films described herein have tensile stresses of less than about 34 MPa or compressive stresses.

While the foregoing is directed to embodiments of the present invention, other and further embodiments of the invention may be devised without departing from the basic scope thereof, and the scope thereof is determined by the claims that follow.

1. A method for depositing a low dielectric constant film, comprising:
delivering a gas mixture comprising:
a cyclic organosiloxane; and
two or more oxidizing gases comprising N₂O and O₂ to a substrate in a chamber, wherein a ratio of a flow rate of the N₂O to a total flow rate of the two or more oxidizing gases into the chamber is between about 0.1 and about 0.5; and
applying RF power to the gas mixture at conditions sufficient to deposit a low dielectric constant film on a surface of the substrate.

2. The method of claim 1, wherein the two or more oxidizing gases consist of N₂O and O₂.

3. The method of claim 1, wherein the cyclic organosiloxane is octamethylcyclotetrasiloxane (OMCTS).

4. The method of claim 1, wherein cyclic organosiloxane is selected from the group consisting of 1,3,5-trimethylcyclotrisiloxane, hexamethylcyclotrisiloxane, 1,3,5,7-tetramethylcyclotetrasiloxane (TMCTS), octamethylcyclotetrasiloxane (OMCTS), 1,3,5,7,9-pentamethylcyclopentasiloxane, and decamethylcyclopentasiloxane.

5. The method of claim 4, wherein the gas mixture further comprises an inert gas selected from the group consisting of helium, argon, and combinations thereof.

6. The method of claim 1, further comprising post-treating the low dielectric constant film with an electron beam.

7. A method for depositing a low dielectric constant film, comprising:
delivering a gas mixture comprising:
a cyclic organosiloxane; and
an oxidizing gas comprising N₂O to a substrate in a chamber, wherein the N₂O is delivered into the chamber at a flow rate between about 0.71 sccm/cm² and about 1.42 sccm/cm²; and
applying RF power to the gas mixture at conditions sufficient to deposit a low dielectric constant film on a surface of the substrate.

8. The method of claim 7, wherein the oxidizing gas consists of N₂O.

9. The method of claim 7, wherein the gas mixture further comprises a linear hydrocarbon.

10. The method of claim 9, wherein the linear hydrocarbon is ethylene.

11. The method of claim 7, wherein the cyclic organosiloxane is octamethylcyclotetrasiloxane (OMCTS).

12. The method of claim 7, wherein the cyclic organosiloxane is selected from the group consisting of 1,3,5-trimethylcyclotrisiloxane, hexamethylcyclotrisiloxane, 1,3,5,7-tetramethylcyclotetrasiloxane (TMCTS), octamethylcyclotetrasiloxane (OMCTS), 1,3,5,7,9-pentamethylcyclopentasiloxane, and decamethylcyclopentasiloxane.

13. The method of claim 7, wherein the gas mixture further comprises an inert gas selected from the group consisting of helium, argon, and combinations thereof.

14. The method of claim 7, further comprising post-treating the low dielectric constant film with an electron beam.

15. A method for depositing a low dielectric constant film, comprising:
delivering a gas mixture comprising:
a cyclic organosiloxane;
a linear hydrocarbon having at least one unsaturated carbon-carbon bond; and
two or more oxidizing gases comprising N₂O and O₂ to a substrate in a chamber; and
applying RF power to the gas mixture at conditions sufficient to deposit a low dielectric constant film on a surface of the substrate.

16. The method of claim 15, wherein the two or more oxidizing gases consist of N₂O and O₂.

17. The method of claim 15, wherein the cyclic organosiloxane is octamethylcyclotetrasiloxane (OMCTS).

18. The method of claim 15, wherein the cyclic organosiloxane is selected from the group consisting of 1,3,5-trimethylcyclotrisiloxane, hexamethylcyclotrisiloxane, 1,3,5,7-tetramethylcyclotetrasiloxane (TMCTS), octamethylcyclotetrasiloxane (OMCTS), 1,3,5,7,9-pentamethylcyclopentasiloxane, and decamethylcyclopentasiloxane.

19. The method of claim 15, wherein the linear hydrocarbon is ethylene.

20. The method of claim 15, wherein the gas mixture further comprises an inert gas selected from the group consisting of helium, argon, and combinations thereof.
